(19) United States
(12) Patent Application Publication
(10) Pub. No.: US 2026/0215197 A1
(43) Pub. Date: Jul. 23, 2026

(54) WAFER BACKSIDE DEPOSITION CLEANING

(71) Applicant: Applied Materials, Inc., Santa Clara, CA (US)

(72) Inventors: Lei He, San Jose, CA (US); Lihua Wu, Fremont, CA (US); Sungwon Ha, Palo Alto, CA (US); Abdul Aziz Khaja, Morgan Hill, CA (US); Daemian Raj Benjamin Raj, Fremont, CA (US); Karthik Janakiraman, San Jose, CA (US)

(73) Assignee: Applied Materials, Inc., Santa Clara, CA (US)

(21) Appl. No.: 19/035,121

(22) Filed: Jan. 23, 2025

(51) Int. Cl. H01L 21/02; H01J 37/32; H01L 21/683

(52) U.S. Cl. CPC H10P 70/20; H01J 37/32715; H10P 72/722; H01J 2237/20235; H01J 2237/3321; H01J 2237/335

(57) ABSTRACT

The present technology is directed to methods and systems for cleaning deposition and/or fill byproducts from a backside or edge of a substrate. Methods include providing one or more deposition and/or fill precursors to a processing region of a semiconductor processing chamber and depositing one or more layers of the deposition and/or fill material on the substrate. Methods include forming a gap between the substrate and a substrate support surface of the substrate support. Methods include generating a DC plasma between the substrate support and a sidewall of the semiconductor processing chamber. Methods include treating the deposition and/or fill material with a DC plasma to remove at least a portion of the deposition and/or fill material from a back side and/or a bevel of the substrate.

### TECHNICAL FIELD

The present technology relates to methods and systems for selective bevel etching during semiconductor manufacturing processes. More specifically, the present technology relates to methods for generating a DC plasma along a side wall of the semiconductor process chamber for selective bevel etching and backside deposition cleaning.

### BACKGROUND

Integrated circuits are made possible by processes which produce intricately patterned material layers on substrate surfaces. Producing patterned material on a substrate requires controlled methods for forming and removing material. Material characteristics may affect how the device operates and may also affect how the films are removed relative to one another. Deposition processes produce films having certain characteristics. Many films that are formed require additional processing to adjust or enhance the material characteristics of the film in order to provide suitable properties.

Thus there is a need for methods that can be used to produce high quality devices and structure. These and other needs are addressed by the present technology.

### BRIEF SUMMARY

The present technology is generally directed to semiconductor processing chambers. Chambers include a substrate support, a first electrode embedded with the substrate support connected to a direct current (DC) power source, a chamber sidewall or portion thereof connected to the direct current (DC) power source, and one or more lift pins. Chambers include where the one or more lift pins have a first position with a top surface of the one or more lift pins generally coplanar with a support surface of the substrate support and a second position wherein the top surface of the one or more lift pins is disposed vertically above the first position, where a gap is formed between a top surface of the one or more lift pins and the substrate support surface in the second position.

In embodiments, chambers include where the gap is from about 5 millimeters to about 200 millimeters when the one or more lift pins are in the second position. Moreover, in embodiments, the DC power source is configured to provide a DC power from about 100 V to about 1000 V. In further embodiments, the chamber sidewall or portion thereof includes a metal sidewall or a metal liner overlying the chamber sidewall. Embodiments include where an exterior edge of a support surface of the substrate support is from about 0.5 inches to about 5 inches from the chamber sidewall. In yet more embodiments, the semiconductor processing chamber is a plasma processing chamber.

The present technology is also generally directed to semiconductor processing methods. Methods include providing one or more deposition and/or fill precursors to a processing region of a semiconductor processing chamber, where a substrate is disposed on a substrate support in a processing region of the semiconductor processing chamber. Methods include depositing one or more layers of the deposition and/or fill material on the substrate, methods include forming a gap between the substrate and a substrate support surface of the substrate support. Methods include generating a DC plasma between the substrate support and a sidewall of the semiconductor processing chamber; and treating the deposition and/or fill material with a DC plasma to remove at least a portion of the deposition and/or fill material from a back side and/or a bevel of the substrate.

In embodiments, methods include where at least a portion of the sidewall of the semiconductor processing chamber is connected to DC power source. Furthermore, in embodiments, a plasma power for generating the DC plasma is from about 100 V to about 1000 V. In more embodiments, the gap is from about 5 millimeters to about 200 millimeters.

The present technology is also generally directed to methods for selectively cleaning an edge or backside of a substrate. Methods include providing one or more deposition and/or fill precursors to a processing region of a semiconductor processing chamber, where a substrate is disposed on a substrate support in a processing region of the semiconductor processing chamber, and where the semiconductor processing chamber is configured to perform a plasma-enhanced chemical-vapor deposition (PECVD) process or a carbon plug-fill operation. Methods include depositing one or more layers of the deposition and/or fill material on the substrate. Methods include forming a gap between the substrate and a substrate support surface of the substrate support. Methods include providing at least one etchant gas to the semiconductor processing chamber and generating a DC plasma between the substrate support and a sidewall of the semiconductor processing chamber.

In embodiments, the gap between the substrate support and the substrate is from about 5 millimeters to about 200 millimeters. Moreover, in embodiments, the at least one etchant gas includes oxygen, carbon dioxide, hydrogen, nitrous oxide, or any combination thereof. In further embodiments, the at least one etchant gas has a flow rate of from 100 sccm to 5000 sccm. Embodiments include pressurizing the semiconductor processing chamber, where the semiconductor processing chamber is pressurized from 100 mTorr to 10 Torr. In yet more embodiments, the substrate support includes a monopolar electrostatic chuck or a bipolar electrostatic chuck. Additionally or alternatively, in embodiments, the plasma is struck between a side wall of the semiconductor processing chamber and the substrate support. Furthermore, in embodiments, the plasma generated simultaneously cleans the backside of the substrate and an edge of the substrate. In embodiments, the cleaning removes at least 75% of the deposition and/or fill material formed on the backside of the substrate and/or an edge of the substrate. In more embodiments, the sidewall or a portion thereof is disposed from about 0.5 inches to about 5 inches from an exterior edge of a support surface of the substrate support.

Such technology may provide numerous benefits over conventional systems and techniques. For example, the processes and systems may allow the use of plasma generated between a substrate support and a chamber sidewall or portion thereof to target cleaning of the bevel and/or backside of a substrate. These and other embodiments, along with many of their advantages and features, are described in more detail in conjunction with the below description and attached figures.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1A shows a schematic cross-sectional view of an exemplary processing chamber according to some embodiments of the present technology.

FIG. 1B shows a schematic cross-sectional view of an exemplary processing chamber wherein the lift pins raise the substrate above the substrate support according to some embodiments of the present disclosure.

FIG. 2 illustrates a flowchart of a method for selectively beveling an edge of a substrate during semiconductor processes, according to some embodiments of the present disclosure.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As device sizes continue to shrink, many material layers may be reduced in thickness and size to scale devices. Features across semiconductor structures may be reduced in size, and aspect ratios of the features may increase. As one example, 3D NAND technology enables high storage density by stacking cells vertically within the limited chip area. However, one step in fabricating 3D NAND is to achieve the carbon plug-filling of memory holes or slits before depositing another ON tier. Due to the active carbon radicals generated during these processes, they can form a layer of carbon film in the area within the sealing band, also referred to as the bevel edge, of the substrate support heater as wafer bowing increases. The wafer backside carbon deposition can lead to integration issues in following steps, such as defects in arcing. This phenomenon is also observed with other film deposition material, and is not reserved to carbon deposition. Backside deposition can also impact the photolithography performance in the downstream chip fabrication.

Conventional methods of performing backside deposition removal may include moving the substrate very close to a faceplate within the semiconductor processing chamber and utilizing a bottom purge. Subsequently an RF plasma may be formed using RF power from the faceplate to clean the backside of the substrate. However, such methods may not adequately clean the backside of the substrate leading to poor performance and less efficient downstream applications, as it is difficult to direct the plasma to the backside of the substrate. Additionally, even with a bottom purge, the generation of an RF plasma along the faceplate and substrate may inadvertently remove areas of the thin film resulting in non-uniformity on the wafer.

The present technology overcomes these and other challenges by generating a DC plasma between the substrate support, or electrostatic chuck, and a sidewall of the semiconductor processing chamber. Namely, the present technology has found that the a grounded side wall or metal liner positioned along or on the sidewall in the semiconductor processing chamber connected to a DC power source allows for targeted cleaning and etching of a substrate edge and/or backside. By striking the plasma between the sidewall and the substrate support, plasma may be directed to the bevel and backside of the substrate, protecting the front side of the substrate. Further, in configurations utilizing DC plasma, the there may be no RF power supplied to the grounded side wall or liner, and may only include DC power. DC plasma generation was once viewed as an undesired side effect of using bipolar electrode designs used for chucking, such as two semicircular electrodes that extend to or beyond the wafer edge. However, the present technology has surprisingly found that by generating a DC plasma at a position along the side wall of the sample processing chamber, the bevel and backside may be selectively etched.

A “substrate” as used herein, refers to any substrate or material surface formed on a substrate upon which film processing is performed during a fabrication process. Additionally, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor substrates. The substrate may be a wafer, wherein the wafer, as a thin film, may be a dielectric thin film. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

After describing general aspects of a chamber according to some embodiments of the present technology in which plasma processing operations discussed below may be performed, specific methodology may be discussed. It is to be understood that the present technology is not intended to be limited to the specific films, chambers or processes discussed, as the techniques described may be used to improve a number of film formation processes, and may be applicable to a variety of processing chambers and operations.

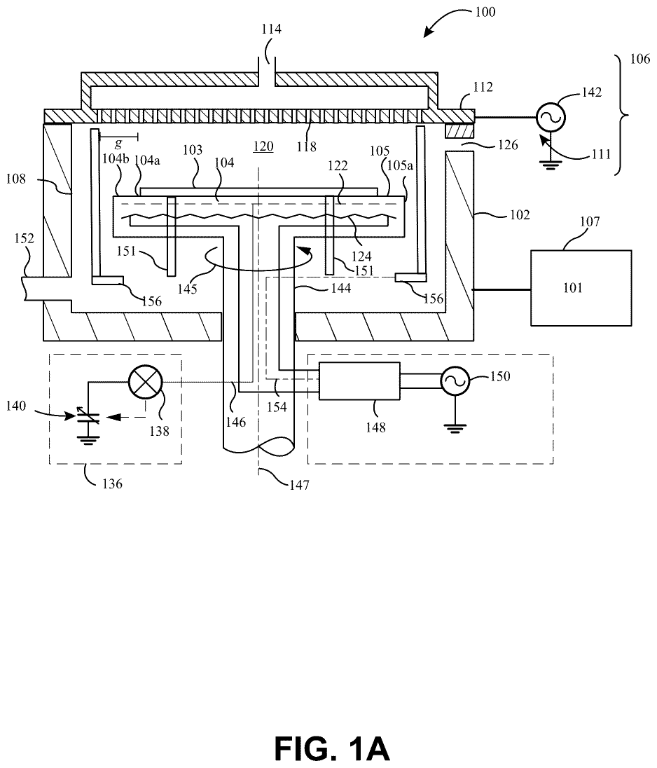

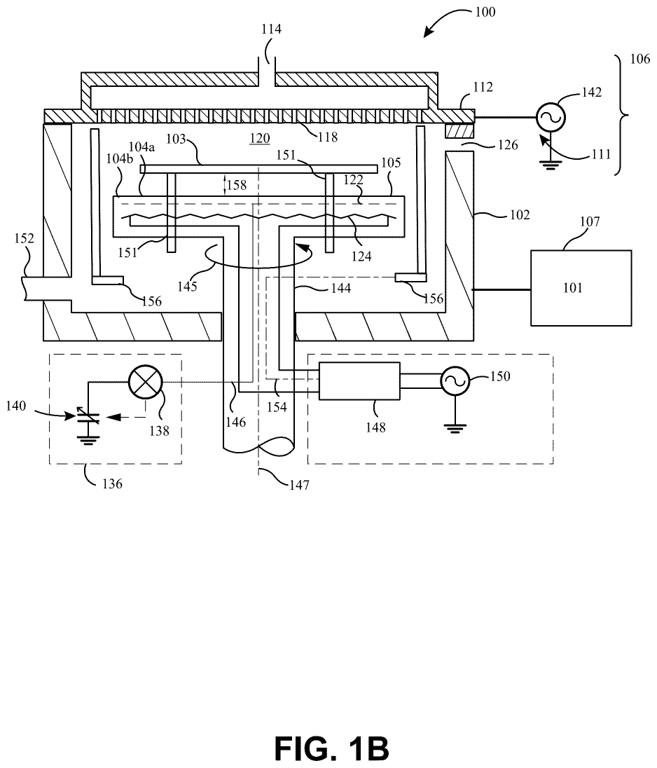

FIG. 1A shows a cross-sectional view of an exemplary processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers, etch material layers, form other material layers, or a combination thereof, although it is to be understood that deposition and etch methods may similarly be performed in any chamber within which deposition and etch processes may occur. The processing chamber 100 may include a chamber body 102, a substrate support 104 disposed inside the chamber body 102, lift pins 151 disposed through the substrate support 104 and configured to lift a substrate 103 off of the substrate support 104, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. In some embodiments, the substrate support 104 may be rotatable, as indicated by the arrow 145, along an axis 147, where a shaft 144 of the substrate support 104 may be located, or may be stationary. Alternatively, the substrate support 104 may be lifted up to rotate as necessary during a deposition process.

A gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIGS. 1A and 1B, or the gas distributor 112 may be coupled with ground in some embodiments.

The lid assembly 106 and substrate support 104 of FIG. 1 may be used with any processing chamber for plasma or thermal processing. In operation, the processing chamber 100 may afford real-time control of plasma conditions in the processing volume 120, such as via a system controller 101 which may be contained within a processor 107. The substrate 103 may be disposed on the substrate support 104, and process gases may be flowed through the lid assembly 106 using an inlet 114 according to any desired flow plan. Gases may exit the processing chamber 100 through an outlet 152.

A first electrode 122 may be coupled with the substrate support 104. The first electrode 122 may be embedded within the substrate support 104 or coupled with a support surface 104a (shown more clearly in FIG. 1B) of the substrate support 104. In embodiments, the support surface 104a may be recessed into the substrate support 104, or may be generally co-planar with the substrate support 104. The substrate support surface 104a may also be referred to as the substrate seat, and may form the surface on which the substrate is placed during processing. A support edge 104b, may be formed by the substrate support 104 or an edge ring, and may surround the support surface 104a. The first electrode 122 may be a plate, a perforated plate, a mesh, a wire screen, or any other distributed arrangement of conductive elements. The first electrode 122 may be a tuning electrode and may be coupled with a tuning circuit 136 by a conduit 146, for example a cable having a selected resistance, such as 50 ohms, for example, disposed in the shaft 144 of the substrate support 104. The tuning circuit 136 may have an electronic sensor 138 and an electronic controller 140, which may be a variable capacitor. The electronic sensor 138 may be a voltage or current sensor and may be coupled with the second electronic controller 140 to provide further control over plasma conditions in the processing volume 120.

A second electrode 124, which may be a bias electrode and/or an electrostatic chucking electrode, may be coupled with the substrate support 104. The second electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be a DC power. The substrate support 104 may also include one or more heating elements configured to heat the substrate to a processing temperature, which may be between about 25° C. and about 800° C. or greater.

The processing chamber 100 may include one or more one or more metal liners 156 positioned in the processing volume and configured to run generally parallel to the chamber body 102 sidewalls 108. However, it should be clear that, in embodiments, the chamber sidewalls 108 or a portion thereof may be metallized as discussed above. Thus, the positioning and orientation discussed herein may refer to a metallized sidewall or portion thereof, a metal liner overlying some or all of the sidewall, or a metal liner disposed generally parallel and adjacent to one or more sidewalls 108. Namely, in embodiments as discussed below, the liner may be disposed inward from the chamber sidewall 108 to control a gap g. Nonetheless, while the one or more one or more metal liners 156 are illustrated as being spaced apart from chamber sidewalls 108, in embodiments, the one or more one or more metal liners 156 may be disposed on, such as directly on in embodiments, the chamber sidewalls 108. The one or more metal liners 156 may be coupled to the second source of electric power 150 through a filter 148. The second source of electric power 150 may be DC power, pulsed DC power, RF bias power, a pulsed RF source or bias power, or a combination of these or other power sources. In some embodiments, the second source of electric power 150 may be a DC power. The one or more metal liners 156 may also be coupled with ground. In some embodiments, the one or more metal liners 156 may be a plate, a perforated plate, a mesh, a wire screen, or any other distributed arrangement of conductive elements. In some embodiments, the one or more metal liners 156 may configured to move horizontally within the sample processing chamber to change the distance an edge of the substrate support 104 to the metal liner 156.

Thus, in embodiments, an exterior edge 105a of a support surface (or alternatively, an exterior edge of substrate 103) of the substrate support 105 and sidewall 108 and/or metal liner 156 may have a gap g of from about 0.5 inches to about 5 inches. For example, the metal liner 156 may be greater than or about 0.5 inches, greater than or about 1.0 inch, greater than or about 1.5 inches, greater than or about 2.0 inches, greater than or about 2.5 inches, greater than or about 3.0 inches, greater than or about 3.5 inches, greater than or about 4.0 inches, greater than or about 4.5 inches, or such as less than or about 5.0 inches, less than or about 4.5 inches, less than or about 4.0 inches, less than or about 3.5 inches, less than or about 3.0 inches, less than or about 2.5 inches, less than or about 2 inches, less than or about 1.5 inches, less than or about 1 inch, or any distance therebetween, from the edge of the substrate support surface. By utilizing one or more distances discussed herein, the plasma may be positioned so as to target bevel and backside deposition of the substrate.

The substrate support 104 may include one or more lift pins 151 disposed through the substrate support 104 and configured to lift a substrate 103 off of the substrate support surface 104a. In some embodiments, the substrate support 104 may include a series of lift pins 151 positioned concentrically about the substrate support 104 to uniformly lift the substrate 103 from the surface 105 of the substrate support 104. As illustrated in FIG. 1A, the one or more lift pins 151 may have a first position where a top surface of the one or more lift pins 151 are generally co-planar with the support surface 104a, allowing the substrate to rest on the support surface 104a. As will be discussed in greater detail below, in a lifted orientation, the top surface of the one or more lift pins 151 may be disposed vertically above the support surface 104a in a second position, forming a gap between a top surface of the lift pins and the support surface 104a. In some embodiments, the substrate support 104 may be an electrostatic chuck. The electrostatic chuck may be a monopolar electrostatic chuck or a bipolar electrostatic chuck.

Additionally, the substrate support 104 may also include an embedded heater contained within the substrate support 104. In some embodiments the first electrode 122 and/or a second electrode 124 may be operated as the heater, but by decoupling these operations, more individual control may be afforded, and extended heater coverage may be provided while limiting the region for plasma formation. Nonetheless, a heater may include multiple heaters in embodiments, and each heater may be associated with a zone of the substrate support 104, and thus may include a similar number or greater number of zones than heaters.

A heater, when utilized may be capable of adjusting temperatures across the substrate support 104, as well as a substrate residing on the substrate support surface 105. The heater may have a range of operating temperatures to heat the substrate support 104 and/or a substrate above or about 100° C., and the heater may be configured to heat above or about 125° C., above or about 150° C., above or about 175° C., above or about 200° C., above or about 250° C., above or about 300° C., above or about 350° C., above or about 400° C., above or about 450° C., above or about 500° C., above or about 550° C., above or about 600° C., above or about 650° C., above or about 700° C., above or about 750° C., above or about 800° C., above or about 850° C., above or about 900° C., above or about 950° C., above or about 1000° C., or higher. The heater may also be configured to operate in any range encompassed between any two of these stated numbers, or smaller ranges encompassed within any of these ranges. In some embodiments, the heater may be operated to maintain a substrate temperature above at least 500° C. during deposition operations. In some embodiments, the heater may be in operation during etching operations. For example, the etching operation may be performing a bevel operation.

DC power may be coupled with the substrate support to establish a plasma in the processing volume 120 along the metal liner 156 and/or on a sidewall 108 of the substrate support 104. The substrate may be subjected to an electrical bias using the second electrode 124 in some embodiments. In some embodiments, the plasma may be confined to the side wall of the substrate 103 and one or more metal liners 156. The side plasma may be used to clean the bevel or edge of the substrate 103. In some embodiments, the side wall plasma may simultaneously clean a back side of the substrate 103.

Upon energizing a plasma in the processing volume 120, a potential difference may be established between the plasma and the first electrode 122. A potential difference may also be established between the plasma and the second electrode 124, such as via sidewall 108 and/or metal liner 156. The electronic controller 140 may then be used to adjust the flow properties of the ground paths represented by the tuning circuit 136. A set point may be delivered to the first circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Tuning circuit 136 may have a variable impedance that may be adjusted using the electronic controller 140. Where the electronic controller 140 is a variable capacitor, the capacitance range of each of the variable capacitors, may be chosen to provide an impedance range. This range may depend on the frequency and voltage characteristics of the plasma, which may have a minimum in the capacitance range of each variable capacitor. Hence, when the capacitance of the electronic controller 140 is at a minimum or maximum, impedance of the tuning circuit 136 may be high, resulting in a plasma shape that has a minimum aerial or lateral coverage over the substrate support. When the capacitance of the electronic controller 140 approaches a value that minimizes the impedance of the tuning circuit 136, the aerial coverage of the plasma may grow to a maximum, effectively covering the entire working area of the substrate support 104. As the capacitance of the electronic controller 140 deviates from the minimum impedance setting, the plasma shape may shrink from the chamber walls and aerial coverage of the substrate support may decline.

The electronic sensor 138 may be used to tune the circuit 136 in a closed loop. A set point for current or voltage, depending on the type of sensor used, may be installed in each sensor, and the sensor may be provided with control software that determines an adjustment to the respective electronic controller 140 to minimize deviation from the set point. Consequently, a plasma shape may be selected and dynamically controlled during processing. It is to be understood that, while the foregoing discussion is based on electronic controller 140, which may be a variable capacitor, any electronic component with adjustable characteristic may be used to provide tuning circuit 136 with adjustable impedance.

Processing chamber 100 may be utilized in some embodiments of the present technology for processing methods that may include formation, etching, conversion of materials for semiconductor structures, or deposition cleaning methods. It is to be understood that the chamber described is not to be considered limiting, and any chamber that may be configured to perform operations as described may be similarly used. FIG. 1B shows a schematic cross-sectional view of an exemplary processing chamber 100 wherein the lift pins 151 are raised to a second position, to lift a substrate 103 to a position above the substrate support 104 and produce a gap 158 according to some embodiments of the present technology.

In some embodiments, the gap 158 generated between the substrate 103 and/or top surface of lift pins 151, when the lift pins are in a second position, and a support surface of the substrate support may be from about 5 millimeters to about 200 millimeters. For example, the gap may be greater than or about 5 millimeters, greater than or about 10 millimeters, greater than or about 15 millimeters, greater than or about 20 millimeters, greater than or about 25 millimeters, greater than or about 30 millimeters, greater than or about 35 millimeters, greater than or about 40 millimeters, greater than or about 45 millimeters, greater than or about 50 millimeters, greater than or about 55 millimeters, greater than or about 60 millimeters, greater than or about 65 millimeters, greater than or about 70 millimeters, greater than or about 75 millimeters, greater than or about 80 millimeters, greater than or about 85 millimeters, greater than or about 90 millimeters, greater than or about 95 millimeters, greater than or about 100 millimeters, greater than or about 105 millimeters, greater than or about 110 millimeters, greater than or about 115 millimeters, greater than or about 120 millimeters, greater than or about 125 millimeters, greater than or about 130 millimeters, greater than or about 135 millimeters, greater than or about 140 millimeters, greater than or about 145 millimeters, greater than or about 150 millimeters, greater than or about 155 millimeters, greater than or about 160 millimeters, greater than or about 165 millimeters, greater than or about 170 millimeters, greater than or about 175 millimeters, greater than or about 180 millimeters, greater than or about 185 millimeters, greater than or about 190 millimeters, greater than or about 195 millimeters, or such as less than or about 200 millimeters, less than or about 195 millimeters, less than or about 190 millimeters, less than or about 185 millimeters, less than or about 180 millimeters, less than or about 175 millimeters, less than or about 170 millimeters less than or about 165 millimeters, less than or about 160 millimeters, less than or about 155 millimeters, less than or about 150 millimeters, less than or about 145 millimeters, less than or about 140 millimeters, less than or about 135 millimeters less than or about 130 millimeters, less than or about 125 millimeters, less than or about 120 millimeters, less than or about 115 millimeters, less than or about 110 millimeters, less than or about 105 millimeters, less than or about 100 millimeters, less than or about 95 millimeters, less than or about 90 millimeters, less than or about 85 millimeters, less than or about 80 millimeters, less than or about 75 millimeters, less than or about 70 millimeters, or any ranges or values therebetween. Namely, the present technology has found that if too large of a gap or too small of a gap is utilized, etching of a top of the substrate may occur instead of being focused on the bevel and/or backside of the substrate.

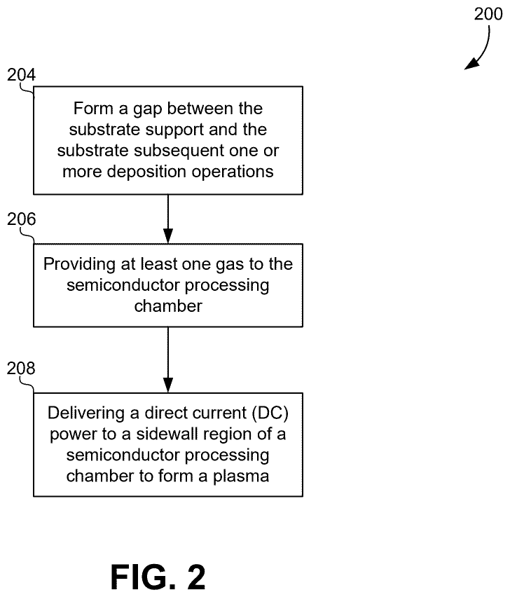

FIG. 2 shows exemplary operations in a processing method 200 according to some embodiments of the present technology. The method may be performed with a variety of processing chambers and on one or more mainframes or tools, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

Moreover, while various deposition and fill processes will be described, it should be understood that, in embodiments, the semiconductor structure may be transferred to and between one or more process chambers configured for deposition and/or fill processes, including chambers for: chemical vapor deposition (CVD), physical vapor deposition (PVD), atomic layer deposition (ALD), thermally enhanced chemical vapor deposition (CVD), plasma-enhanced chemical vapor deposition (PECVD), plasma enhanced atomic layer deposition (PEALD), or the like. Thus, unless specified, it should be understood that any one or more of the above methods may be utilized as known in the art. Similarly, the semiconductor structure may be transferred to and between one or more process chambers configured for etching, such as one or more of inductively coupled plasma (ICP) etching, reactive ion etching (RIE), capacitively coupled plasma (CCP) etching, or the like, as well as other etching processes as known in the art.

In embodiments, the method may include supporting a substrate on a substrate support in a semiconductor processing chamber and subjecting the substrate to one or more deposition and/or fill processes, such as one or more deposition and/or fill processes discussed above. In embodiments, the semiconductor processing chamber may be configured to perform a plasma-enhanced chemical-vapor deposition (PECVD) process, as an example only, that forms a film on a surface of the substrate. As an example only, the semiconductor processing chamber may be configured to perform carbon plug-fill operations for 3D NAND applications. In some embodiments, prior to or subsequent to the one or more deposition and fill processes, the method may include performing carbon plug-filling of memory holes or slits before deposition of a second ON tier. For example, the deposition process may include forming alternating oxide and nitride layers in an ON stack. The deposition process may also include forming a relatively thick layer of silicon oxide (e.g., using a TEOS precursor) that is greater than 10 μm, greater than 15 μm, greater than 20 μm, greater than 25 μm, greater than 30 μm, or larger. The substrate may be formed from silicon, silicon germanium, or other substrate materials. The layers may include IPD layers of ON layers, including a dielectric material, which may be silicon oxide, in alternating layers with a placeholder material, which may be silicon nitride or polysilicon, for example. In some embodiments, the number of film layers may be very large and may include 10 or more layer pairs, 20 more layer pairs, 50 or more layer pairs, 100 or more layer pairs, and so forth. For example, a height of the semiconductor structure may be more than 10 μm, more than 20 μm, and so forth. The process may also be a plasma-enhanced etch process or any other plasma process. However, it should be clear that the bevel and/or backside cleaning operations discussed herein may be utilized for the removal of other deposition and fill materials, and that carbon plug fill deposition is described as an example only.

Namely, in embodiments, due to the active radicals formed during deposition and fill operations, a layer of the deposition and/or fill material may be formed in the area within the sealing band of the substrate support, particularly as substrate bowing increases. Backside and/or bevel deposition may lead to integration issues such as defects and arcing, during subsequent processing. Thus, described further below is a method for bevel and/or backside deposition cleaning, which may be in-situ, in embodiments, with side DC plasma generation.

For instance, in embodiments, the method includes forming a gap between the substrate and substrate support, such as via lifting in embodiments, subsequent to one or more deposition and/or fill operations at operation 204. In embodiments, the formation of the gap and/or lifting may be performed via lift pins 151 positioned concentrically about the substrate support 104. The lift pins 151 may lift the substrate 103 to a predetermined position above the substrate support. For example, the gap may be from about 5 millimeters to about 200 millimeters, or any one or more of the ranges discussed above. In some embodiments, the plasma confinement may be varied and/or controlled via changing the gap between the substrate and the substrate support surface. The plasma confinement may change the penetration of the plasma on the back side of the substrate as discussed above.

The method may also include providing at least one gas to the semiconductor processing chamber at operation 206. In some embodiments, the at least one gas may be a precursor gas and/or etchant gas, alone or in combination with one or more inert or carrier gasses. However, in embodiments, the at least one gas includes one or more etchant gasses alone or in combination with at least one inert or carrier gas. In some embodiments, the precursor or etchant gas may be a carbon containing gas, an oxygen containing gas, a nitrogen containing gas, or a hydrogen-containing gas, such as oxygen, carbon dioxide, hydrogen, nitrous oxide, or combinations thereof. However, it should be clear that the etchant gas may be one or more etchant gasses known in the art, and may be selected based upon the material to be etched. The precursor gas may include a material for the film to be formed on the substrate. The at least one gas may include carrier or inert gases, such as nitrogen, helium, argon, hydrogen or other noble, inert, or useful precursors. In embodiments, the precursor may also include gas species that include a material for the film, such as TEOS, C, O₂, N₂O, SiH₄, NH₃, N₂, and so forth. In some embodiments, the etchant gas may be oxygen, carbon dioxide, hydrogen, nitrous oxide or any combination thereof and/or the inert gas may be one or more of argon, nitrogen, hydrogen, or combinations thereof.

Flow rates for the precursor gas or etchant gas during this step may range from between about 0 sccm to about 13000 sccm. For example, the flow rates may range from between about 0 sccm to about 10000 sccm, between about 100 sccm to about 5000 sccm, between about 200 sccm to about 4000 sccm, between about 300 sccm to about 3000 sccm, between about 400 sccm to about 2000 sccm, between about 500 sccm to about 1000 sccm, and/or any combination of ranges therebetween. The one or more process gasses may be flowed from a top, bottom (e.g. along or through the pedestal aperture), and/or side of the chamber (such as through or adjacent to outlet 152 in embodiments) due to the unique position of the sidewall electrode discussed herein. For instance, in embodiments, all gasses (e.g. inert gasses and etchant chemistry) may be flowed from a top of the chamber and/or all gasses may be flowed from a bottom of the chamber. In still further embodiments, a portion of the gasses, such as the one or more inert gas may be flowed from a top while one or more etchant gasses may be flowed from a bottom and/or side. Moreover, in embodiments, a portion of the gasses, such as one or more etchant gasses may be flowed from a top while one or more inert gasses may be flowed from a bottom and/or side.

In embodiments, the flowing may be of one or more etchant gasses such as a carbon containing gas, an oxygen containing gas, a nitrogen containing gas, or a hydrogen-containing gas, or any combination thereof. In embodiments, the etchant gas may be for removal of a carbon containing film. In such embodiments, the one or more other etchant gasses may be flowed at a rate of about 100 sccm or greater, greater than or about 200 sccm, greater than or about 300 sccm, greater than or about 400 sccm, greater than or about 500 sccm, greater than or about 600 sccm, greater than or about 700 sccm, greater than or about 800 sccm, greater than or about 900 sccm, greater than or about 1000 sccm, greater than or about 1250 sccm, greater than or about 1500 sccm, greater than or about 1750 sccm, greater than or about 2000 sccm, greater than or about 2250 sccm, greater than or about 2500 sccm, greater than or about 2750 sccm, greater than or about 3000 sccm, greater than or about 3250 sccm, greater than or about 3500 sccm, greater than or about 3750 sccm, greater than or about 4000 sccm, greater than or about 4250 sccm, greater than or about 4500 sccm, or such as less than or about 5000 sccm, less than or about 4900 sccm, less than or about 4800 sccm, less than or about 4700 sccm, less than or about 4600 sccm, less than or about 4500 sccm, less than or about 4400 sccm, less than or about 4300 sccm, less than or about 4200 sccm, less than or about 4100 sccm, less than or about 4000 sccm, less than or about 3750 sccm, less than or about 3500 sccm, less than or about 3250 sccm, less than or about 3000 sccm, less than or about 2750 sccm, less than or about 2500 sccm, less than or about 2250 sccm, less than or about 2000 sccm, less than or about 1750 sccm, less than or about 1500 sccm, less than or about 1250 sccm, less than or about 1000 sccm, or any ranges or values therebetween.

Similarly, carrier or inert gasses, such as nitrogen, helium, argon, hydrogen or other noble, inert, or useful carrier gasses may be flowed at a rate of about 100 sccm or greater, greater than or about 200 sccm, greater than or about 300 sccm, greater than or about 400 sccm, greater than or about 500 sccm, greater than or about 600 sccm, greater than or about 700 sccm, greater than or about 800 sccm, greater than or about 900 sccm, greater than or about 1000 sccm, or such as less than or about 1500 sccm, less than or about 1400 sccm, less than or about 1300 sccm, less than or about 1200 sccm, less than or about 1100 sccm, less than or about 1000 sccm, less than or about 900 sccm, less than or about 800 sccm, less than or about 700 sccm, less than or about 600 sccm, less than or about 500 sccm, less than or about 400 sccm, less than or about 300 sccm, less than or about 200 sccm, less than or about 100 sccm, or any ranges or values therebetween. However, it should be clear that other etchant gasses are contemplated herein. In embodiments, the nitrous oxide and/or oxygen may further improve backside and/or bevel etching as compared to front side etching.

In embodiments, the method may optionally include sequentially depositing a carbon-containing material or one or more other deposition and/or fill materials, onto the substrate, followed by treating the carbon-containing material with plasma effluents of the hydrogen-containing precursor. The process may be repeated for any number of cycles. When cycling the deposition and etching of the carbon-containing material, the one or more features may iteratively fill higher in a bottom up gap-fill, such as towards the top of the feature, during each deposition and treatment sequence. In some embodiments, the methods described herein may be performed following each deposition sequence with the carbon-containing precursor. For example, the carbon-containing material may extend within one or more recessed features along the substrate. In some embodiments, the treatment step may be performed using the DC plasma generated between the substrate support and the metal liner positioned within the semiconductor processing chamber.

The method may additionally include forming a plasma from the one or more etchant gasses in the semiconductor processing chamber at operation 208 subsequent to one or more deposition and/or fill cycles of the one or more deposition and/or fill materials. In some embodiments, to discharge or form the plasma, the substrate support 104 heater may be used as the negative cathode and the chamber sidewall 108 or metal liner 156 may be used as the positive anode. The DC side plasma is thus formed by tuning the DC voltage and pressure. The temperature within the processing chamber or at the substrate level may be maintained between about 200° C. and about 700° C. in embodiments. The temperature may be maintained above or about 200° C., and may be maintained above or about 250° C., above or about 300° C., above or about 350° C., above or about 400° C., above or about 450° C., above or about 500° C., above or about 550° C., above or about 600° C., above or about 650° C., above or about 700° C., or higher, or such as less than or about 1000° C., less than or about 900° C., less than or about 800° C., less than or about 700° C., or any ranges or values therebetween. The pressure may be maintained below or about 15 Torr, and may be maintained below or about 10 Torr, below or about 5 Torr, below or about 4 Torr, below or about 3 Torr, below or about 2 Torr, below or about 1 Torr, below or about 500 mTorr, below or about 100 mTorr or lower. In embodiments the pressure may be maintained between about 500 mTorr and about 10 Torr, or any ranges or values therebetween as discussed above.

In some embodiments, the DC voltage applied across the substrate support and the chamber sidewall or metal liner may range from between about 100 V to about 1500 V. For example, the plasma power may be greater than or about 100 V, greater than or about 200 V, greater than or about 300 V, greater than or about 400 V, greater than or about 500 V, greater than or about 600 V, greater than or about 700 V, greater than or about 800 V, greater than or about 900 V, greater than or about 1000 V, or such as less than or about 1500 V, less than or about 1400 V, less than or about 1300 V, less than or about 1200 V, less than or about 1100 V, less than or about 1000 V, less than or about 900 V, less than or about 800 V, less than or about 700 V, less than or about 600 V, less than or about 500 V, less than or about 400 V, less than or about 300 V, or any ranges or values therebetween.

By utilizing the unique sidewall plasma strike discussed here, alone or in combination with one or more of the spacing and process conditions discussed herein, backside deposition removal etch rate may be at least 3 times higher than the front side etch rate. In some embodiments, the backside etch rate may be from at least 3 time to at least 10 times higher than the front side etch rate. For example, the backside etch rate may be greater than or about 3 times, greater than or about 4 times, greater than or about 5 times, greater than or about 6 times, greater than or about 7 times, greater than or about 8 times, greater than or about 9 times, or greater than or about 10 times higher than the etching rate on the frontside of the substrate. In some embodiments, the backside etch rate may be achieved via the use of side plasma from DC power. For example, methods currently employed may use RF plasma generated from a top feed in the sample processing chamber. The RF plasma may be struck from the substrate surface and the faceplate of the lid above the sample processing chamber. Thus, the plasma is generated on the top Surface of the substrate and may remove, or etch, the thin film produced during the chemical vapor deposition. Thus, striking the DC plasma on a side wall of the sample processing chamber may allow for cleaning of the substrate backside while simultaneously selectively etching a bevel onto the substrate surface. Thus, the methods described herein may be used for selectively beveling an edge or substrate backside cleaning following carbon plug-fill processes.

In embodiments, the backside deposition removal time may be tuned based on the backside deposition thickness. For example, the carbon removal rate from the wafer backside may be from about 400 A/min to about 800 A/min or any value within the range. For example. The removal rate may be about 400 A/min, about 420 A/min, about 440 A/min, about 460 A/min, about 480 A/min, about 500 A/min, about 520 A/min, about 540 A/min, about 560 A/min, about 580 A/min, about 600 A/min, about 620 A/min, about 640 A/min, about 660 A/min, about 680 A/min, about 700 A/min, about 720 A/min, about 740 A/min, about 760 A/min, about 780 A/min, about 800 A/min, or any rate therebetween.

In embodiments, the plasma confinement may be varied and/or controlled via changing the gap between the substrate and the substrate support surface. The plasma confinement may change the penetration of the plasma on the back side of the substrate.

In some embodiments, the backside deposition cleaning as described herein may remove at least 70 % of the one or more deposition and/or fill materials formed on the back side and/or bevel of the substrate. For example, the method may remove at least 71 %, at least 72 %, at least 73 %, at least 74 %, at least 75 %, at least 76 %, at least 77 %, at least 78 %, at least 79 %, at least 80 %, at least 81 %, at least 82 %, at least 83 %, at least 84 %, at least 85 %, at least 86 %, at least 87 %, at least, 88 %, at least 89 %, at least 90 %, at least 91 %, at least 92 %, at least 93 %, at least, 94 %, at least 95 %, at least 96 %, at least 97 %, at least 98 %, or at least 99 % of the one or more deposition and/or fill materials on the back side and/or bevel of the substrate.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a metal” includes a plurality of such metals, and reference to “the layer” includes reference to one or more layers and equivalents thereof known to those skilled in the art, and so forth.

As used herein, the terms “about” or “approximately” or “substantially” may be interpreted as being within a range that would be expected by one having ordinary skill in the art in light of the specification, namely may be used to modify a value, indicates that the value can be raised or lowered by 10% and remain within the disclosed aspect, such as 7.5%, such as 5%, such as 4%, such as 3%, such as 2%, such as 1 %, or any ranges or values therebetween. Moreover, the term “substantially free of” is not to be limited to entirely or completely free of and may correspond to a lack of any appreciable or detectable amount of the recited substance in the material, such as less than the precision of an industry-accepted instrument or test for measuring the amount of the substance in the material. For instance, in embodiments, a material may be “substantially free of” a substance when the amount of the substance in the material is less than 10%, less than 9%, less than 8%, less than 7%, less than 6%, less than 5%, less than 4%, less than 3%, less than 2%, less than 1 %, less than 0.5%, or less than 0.1 % by weight of the material.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing chamber comprising:
a substrate support;
a first electrode embedded with the substrate support connected to a direct current (DC) power source;
a chamber sidewall or portion thereof connected to the direct current (DC) power source; and
one or more lift pins having a first position with a top surface of the one or more lift pins generally coplanar with a support surface of the substrate support and a second position wherein the top surface of the one or more lift pins is disposed vertically above the first position, wherein a gap is formed between a top surface of the one or more lift pins and the substrate support surface in the second position.

2. The semiconductor processing chamber of claim 1, wherein the gap is from about 5 millimeters to about 200 millimeters when the one or more lift pins are in the second position.

3. The semiconductor processing chamber of claim 1, wherein the DC power source is configured to provide a DC power from about 100 V to about 1000 V.

4. The semiconductor processing chamber of claim 1, wherein the chamber sidewall or portion thereof comprises a metal sidewall or a metal liner overlying the chamber sidewall.

5. The semiconductor processing chamber of claim 1, wherein an exterior edge of a support surface of the substrate support is from about 0.5 inches to about 5 inches from the chamber sidewall.

6. The semiconductor processing chamber of claim 1, wherein the semiconductor processing chamber comprises a plasma processing chamber.

7. A semiconductor processing method comprising;
providing one or more deposition and/or fill precursors to a processing region of a semiconductor processing chamber, wherein a substrate is disposed on a substrate support in a processing region of the semiconductor processing chamber;
depositing one or more layers of the deposition and/or fill material on the substrate;
forming a gap between the substrate and a substrate support surface of the substrate support;
generating a DC plasma between the substrate support and a sidewall of the semiconductor processing chamber; and
treating the deposition and/or fill material with a DC plasma to remove at least a portion of the deposition and/or fill material from a back side and/or a bevel of the substrate.

8. The method of claim 7, wherein at least a portion of the sidewall of the semiconductor processing chamber is connected to DC power source.

9. The method of claim 7, wherein a plasma power for generating the DC plasma is from about 100 V to about 1000 V.

10. The method of claim 7, wherein the gap is from about 5 millimeters to about 200 millimeters.

11. A method for selectively cleaning an edge or backside of a substrate comprising:
providing one or more deposition and/or fill precursors to a processing region of a semiconductor processing chamber, wherein a substrate is disposed on a substrate support in a processing region of the semiconductor processing chamber, wherein the semiconductor processing chamber is configured to perform a plasma-enhanced chemical-vapor deposition (PECVD) process or a carbon plug-fill operation;
depositing one or more layers of the deposition and/or fill material on the substrate;
forming a gap between the substrate and a substrate support surface of the substrate support;
providing at least one etchant gas to the semiconductor processing chamber; and
generating a DC plasma between the substrate support and a sidewall of the semiconductor processing chamber.

12. The method of claim 11, wherein the gap between the substrate support and the substrate is from about 5 millimeters to about 200 millimeters.

13. The method of claim 11, wherein the at least one etchant gas comprises oxygen, carbon dioxide, hydrogen, nitrous oxide, or any combination thereof.

14. The method of claim 13, wherein the at least one etchant gas has a flow rate of from 100 sccm to 5000 sccm.

15. The method of claim 11, further comprising pressurizing the semiconductor processing chamber, wherein the semiconductor processing chamber is pressurized from 100 mTorr to 10 Torr.

16. The method of claim 11, wherein the substrate support comprises a monopolar electrostatic chuck or a bipolar electrostatic chuck.

17. The method of claim 11, wherein the plasma is struck between a side wall of the semiconductor processing chamber and the substrate support.

18. The method of claim 17, wherein the plasma cleans the backside of the substrate and an edge of the substrate.

19. The method of claim 18, wherein the cleaning removes at least 75% of the deposition and/or fill material formed on the backside of the substrate and/or an edge of the substrate.

20. The method of claim 11, wherein the sidewall or a portion thereof is disposed from about 0.5 inches to about 5 inches from an exterior edge of a support surface of the substrate support.
